(19) United States
(12) Patent Application Publication
(10) Pub. No.: US 2013/0333927 A1
(43) Pub. Date: Dec. 19, 2013

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Hyun Chul Cho, Suwon (KR); Kei Won, Suwon (KR); Young Min Yun, Suwon (KR); Hwa Sub Oh, Suwon (KR)

(21) Appl. No.: 13/916,364

(22) Filed: Jun. 12, 2013

(30) Foreign Application Priority Data
Jun. 13, 2012 (KR) 10-2012-0063313

(51) Int. Cl. H05K 1/03; H05K 3/42

(52) U.S. Cl. CPC H05K 1/032; H05K 3/42
USPC 174/255; 174/262; 29/852

(57) ABSTRACT

Disclosed herein is a method of manufacturing a printed circuit board, the method including: preparing a base substrate having one surface and the other surface; forming first signal metal layers including a first signal via penetrating the base substrate from one surface to the other surface and first heat dissipation metal layers on the base substrate; and forming a build-up layer on the base substrate by forming second heat dissipation metal layers including second signal metal layers including second signal vias stacked on the first signal via and a heat dissipation via penetrating the base substrate and the build-up layer in the thickness direction.

### CROSS REFERENCE TO RELATED APPLICATION

This application claims the benefit of Korean Patent Application No. 10-2012-0063313, filed on Jun. 13, 2012, entitled “Printed circuit board and method of manufacturing the same”, which is hereby incorporated by reference in its entirety into this application.

### BACKGROUND OF THE INVENTION

1. Technical Field

The present invention relates to a printed circuit board and a method of manufacturing the same.

2. Description of the Related Art

As markets of mobile devices expand, there have been increasing demands for a printed circuit board which is smaller, cheaper, and more capable.

Various printed circuit boards such as disclosed in Patent Document 1, for example, have a challenge to meet such demands of the market without degrading heat dissipation characteristics under high-temperature operations.

### PRIOR ART DOCUMENT

### Patent Document

(Patent Document 1) US 2006-0191709 A

### SUMMARY OF THE INVENTION

The present invention has been made in an effort to provide a printed circuit board for improving a heat dissipation efficiency and the degree of freedom in design, and a method of manufacturing the same.

According to a first preferred embodiment of the present invention, there is provided a method of manufacturing a printed circuit board, the method including: preparing a base substrate having one surface and the other surface; forming on the base substrate first signal metal layers including a first signal via penetrating the base substrate from one surface to the other surface and first heat dissipation metal layers; and forming on the base substrate a build-up layer by forming second heat dissipation metal layers including second signal metal layers including second signal vias stacked on the first signal via and a heat dissipation via penetrating the base substrate and the build-up layer in the thickness direction.

In the preparing of the base substrate, the base substrate may be made of a copper clad laminate layer.

In the forming of the first signal metal layers and the first heat dissipation metal layers, the first signal via may have a sandglass shape.

The via holes for forming the first and second signal vias may be formed through a laser drilling process.

In the forming of the first signal metal layers and the first heat dissipation metal layers, the via hole for forming the first signal via may be formed through drilling from both one surface and the other surface of the base substrate.

The forming of the first signal metal layers and the first heat dissipation metal layers may include: forming a via hole for the first signal via penetrating the base substrate from one surface to the other surface; and forming the first signal metal layers including the first signal via formed in the via hole for the first signal via, and the first heat dissipation metal layers.

The forming of the build-up layer may include: forming an isolation layer on the base substrate; forming a metal layer on the isolation layer; forming via holes for the second signal vias in the isolation layer and the metal layer, and forming a via hole for heat dissipation via penetrating the base substrate and the build-up layer in the thickness direction of the substrate; and forming the build-up layer by forming the second signal metal layers including the second signal vias in the via holes for the second signal via hole and forming the second heat dissipation metal layers including the heat dissipation via in the via hole for the heat dissipation via.

The via hole for forming the heat dissipation via may be formed through a mechanical drilling process.

The method may further include forming a solder resist layer having an opening for exposing a pad formed on the build-up layer, after the forming of the build-up layer.

According to a second preferred embodiment of the present invention, there is provided a printed circuit board, including: a base substrate having one surface and the other surface, and including first signal metal layers including a first signal via penetrating the base substrate from one surface to the other surface and first heat dissipation metal layers; a build-up layer being formed on the base substrate, and including second signal metal layers including second signal vias stacked on the first signal via and second heat dissipation metal layers facing the first heat dissipation metal layer; and a heat dissipation via penetrating the base substrate and the build-up layer in the thickness direction of the substrate, wherein the heat dissipation via penetrates the first heat dissipation metal layers in the thickness direction to reach the second heat dissipation metal layers.

The base substrate may be made of a copper-clad laminate.

The first signal via may have a sandglass shape.

The build-up layer may further include an isolation layer including openings for the second signal vias and the heat dissipation via.

The printed circuit board may further include a solder resist layer having an opening for exposing a pad formed on the build-up layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a configuration of a printed circuit board according to a preferred embodiment of the present invention;

FIGS. 2 to 6 are cross-sectional views sequentially showing a method for manufacturing a printed circuit board according to a preferred embodiment of the present invention;

FIG. 7 is a view showing an example of a signal via formed through a laser drilling processing according to a preferred embodiment of the present invention; and

FIG. 8 is a view showing an example of a heat dissipation via formed through a mechanical drilling processing according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

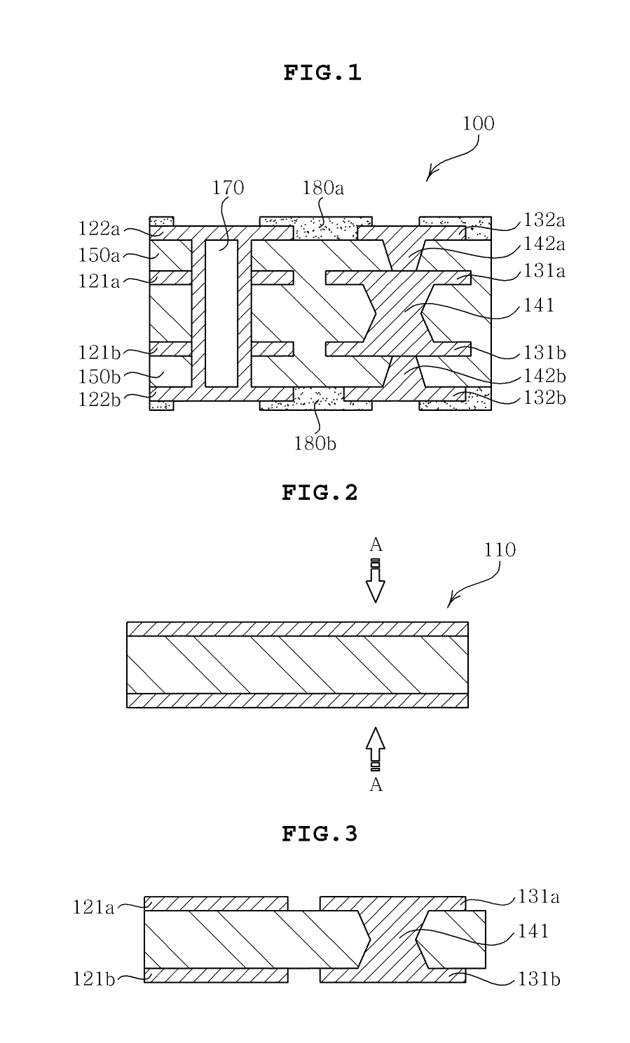

FIG. 1 is a cross-sectional view showing a configuration of a printed circuit board according to a preferred embodiment of the present invention.

As shown in FIG. 1, the printed circuit board 100 may be configured to include: a base substrate having one surface and the other surface and including first signal metal layers 131a, 131b including a first signal via 141 penetrating the base substrate from one surface to the other surface and first heat dissipation metal layers 121a, 121b; a build-up layer being formed on the base substrate and including second signal metal layers 132a, 132b including second signal vias 142a, 142b stacked on the first signal via 141 and second heat dissipation layer 122a, 122b facing the first heat dissipation metal layers 121a, 121b, respectively; and a heat dissipation via 170 penetrating the bas substrate and the build-up layer in the thickness direction of the substrate.

The heat dissipation via 170 may formed so that it penetrates the first heat dissipation metal layers 121a, 121b in the thickness direction to reach the second heat dissipation metal layers 122a, 122b.

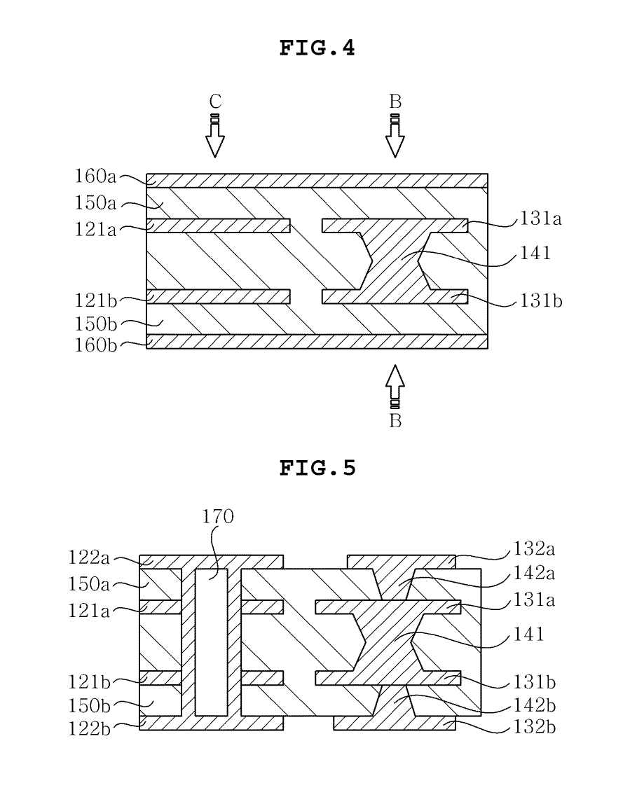

The base substrate (110 in FIG. 2) may be made of a copper-clad laminate.

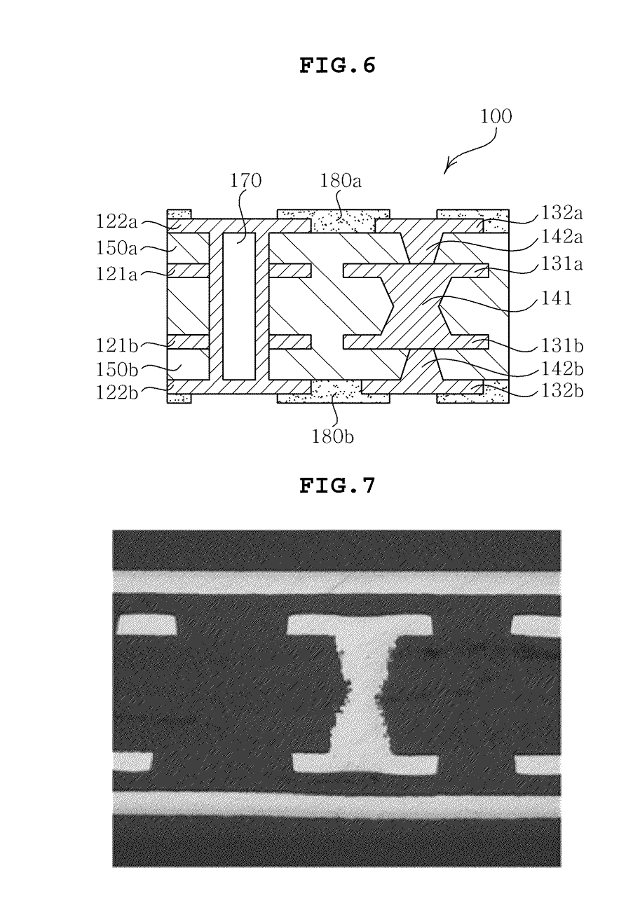

Further, as shown in FIGS. 1 and 7, the first signal via 141 may have a sandglass shape.

The build-up layer may further include isolation layers 150a, 150b having openings for the second signal vias 142a, 142b and the heat dissipation via 170. That is, the build-up layer may include isolation layers 150a, 150b which are inter-layer isolation layers, patterned second signal metal layers 132a, 132b and second heat dissipation metal layers 122a, 122b.

Further, the printed circuit board 100 may include solder resist layers 180a, 180b having openings for exposing a pad formed on the build-up layer.

The via holes for forming the first and second signal vias 141, 142a, 142b may be formed through a laser drilling process whereas the via hole for forming the heat dissipation via 170 may be formed through a mechanical drilling processing.

Since the heat dissipation via 170 is formed through a mechanical drilling process, the hole size is larger than the hole size formed through a laser drilling process, thereby improving heat dissipation characteristic in the printed circuit board 100 due to the increased heat dissipation area.

In addition, according to the preferred embodiment of the present invention, at the time of forming a via hole in a region which requires heat dissipation, the via hole is formed through a mechanical drilling processing instead of a laser drilling processing, such that the degree of freedom in varying the thickness of a copper foil may be improved.

Specifically, a copper foil used for a laser drilling process has a limit on its thickness for the reason that, when holes are closely arranged, lasers may overlap one another since the size of the lasers is bigger than the size of the holes, such that holes at the overlapped position may be broken down unless the copper foil is thick enough.

Further, since a copper foil having a thickness at which a laser drilling processing is applicable is too thick to apply a direct CO2 laser drilling processing, an additional process to open the copper foil is required and thus manufacturing cost is increased.

In contrast, since the via hole in the heat dissipation region of the printed circuit board according to the preferred embodiment of the present invention is formed through a mechanical drilling processing, no additional process is required and no limit exists on the copper foil.

Method for Manufacturing Printed Circuit Board

FIGS. 2 to 6 are cross-sectional views sequentially showing a method for manufacturing a printed circuit board according to a preferred embodiment of the present invention.

As shown in FIG. 2, a base substrate 110 having one surface and the other surface may be prepared.

The base substrate (110) may be made of a copper-clad laminate.

Next, as shown in FIG. 3, first signal metal layers 131a, 131b including a first signal via 141 penetrating the first base substrate from one surface to the other surface, and first heat dissipation metal layers 121a, 121b may be formed on the base substrate 110.

Here, a via hole for forming the first signal via 141 may be formed by drilling with a laser drill from one surface and from the other surface, respectively (A in FIG. 2).

The first signal via 141 may have a sandglass shape.

Specifically, the vial hole for the first signal via penetrating the base substrate 110 from one surface to the other surface may be formed.

Subsequently, the first signal metal layers 131a, 131b including the first signal via 141 formed in the via hole for the first signal via, and the first heat dissipation metal layer 121a, 121b may be formed.

Then, as shown in FIGS. 4 and 5, second signal metal layers 132a, 132b including second signal vias 142a, 142b stacked on the first signal via 141, and second heat dissipation metal layers 122a, 122b including a heat dissipation via 170 penetrating the base substrate 110 and a build-up layer in the thickness direction are formed on the base substrate 110, thereby to form the build-up layer.

The via holes for forming the first and second signal vias 141, 142a, 142b may be formed through a laser drilling process (A in FIG. 2, B in FIG. 4).

Specifically, forming the build-up layer may include forming isolation layers 150a, 150b on the base substrate 110; forming the metal layers 160a, 160b on the isolation layers 150a, 150b; and forming the via holes for the second signal vias in the isolation layer 150a, 150b and the metal layers 160a, 160b and forming a via hole for the heat dissipation via penetrating the base substrate and the build-up layer in the thickness direction.

Further, the forming of the build-up layer may include forming the second signal metal layers 132a, 132b including the second signal vias 142a, 142b in the via holes for the second signal vias, and forming the second heat dissipation metal layers 122, 122b including the heat dissipation via 170 in the via hole for the heat dissipation via.

Here, metal layers 160a, 160b are formed on the isolation layers 105a, 150b prior to forming the second signal metal layers and the second heat dissipation metal layers, and, for the sake of convenience, are denoted with different reference numerals to distinguish them from the second metal layers and the second heat dissipation metal layers.

In addition, the via hole for heat dissipation via may be formed through a mechanical drilling processing (C in FIG. 4).

Since the heat dissipation via 170 according to the preferred embodiment of the present invention is formed using a mechanical drilling, the hole size is larger than the hole size formed using a laser process, thereby improving heat dissipation characteristic in the printed circuit board 100 due to the larger heat dissipation area.

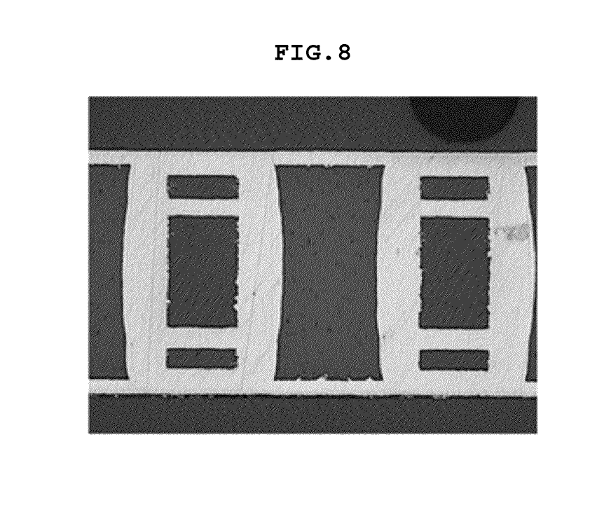

That is, as shown in FIGS. 7 and 8, the heat dissipation via formed through a mechanical drilling processing (FIG. 8) is superior to the signal via formed through a laser drilling processing (FIG. 7) in terms of heat dissipation efficiency since the former has larger volume than the latter.

In addition, according to the preferred embodiment of the present invention, at the time of forming a via hole in a region which requires heat dissipation, the via hole is formed through a mechanical drilling processing instead of a laser drilling processing, such that the degree of freedom in varying the thickness of a copper foil may be improved.

Specifically, a copper foil used for a laser drilling process has a limit on its thickness for the reason that, when holes are closely arranged, lasers may overlap one another since the size of the lasers is bigger than the size of the holes, such that holes at the overlapped position may be broken down unless the copper foil is thick enough.

Further, since a copper foil having a thickness at which a laser drilling processing is applicable is too thick to apply a direct CO2 laser drilling processing, an additional process to open the copper foil is required and thus manufacturing cost is increased.

In contrast, since the via hole in the heat dissipation region of the printed circuit board according to the preferred embodiment of the present invention is formed through a mechanical drilling processing, no additional process is required and no limit exists on the copper foil.

Finally, as shown in FIG. 6, solder resist layers 180a, 180b having openings for exposing a pad may be formed on the build-up layer.

As stated above, in the printed circuit board and the method of manufacturing the same according to the preferred embodiment of the present invention, the signal vias and the heat dissipation vias are formed through a laser drilling process and a mechanical drilling process, thereby improving the degree of freedom in design of a printed circuit board.

Further, according to the preferred embodiment of the present invention, the heat dissipation vias are formed through a mechanical drilling process such that heat dissipation efficiency per unit area can be improved.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method of manufacturing a printed circuit board, the method comprising:
preparing a base substrate having one surface and the other surface;
forming on the base substrate first signal metal layers including a first signal via penetrating the base substrate from one surface to the other surface and first heat dissipation metal layers; and
forming on the base substrate a build-up layer by forming second heat dissipation metal layers including second signal metal layers including second signal vias stacked on the first signal via and a heat dissipation via penetrating the base substrate and the build-up layer in the thickness direction.

2. The method as set forth in claim 1, wherein in the preparing of the base substrate, the base substrate is made of a copper-clad laminate.

3. The method as set forth in claim 1, wherein in the forming of the first signal metal layers and the first heat dissipation metal layers, the first signal via has a sandglass shape.

4. The method as set forth in claim 1, wherein the via hole for forming the first and second signal vias are formed through a laser drilling process.

5. The method as set forth in claim 1, wherein in the forming of the first signal metal layers and the first heat dissipation metal layers, the via hole for forming the first signal via is formed through drilling from both one surface and the other surface of the base substrate.

6. The method as set forth in claim 1, wherein the forming of the first signal metal layers and the first heat dissipation metal layers includes:
forming a via hole for the first signal via penetrating the base substrate from one surface to the other surface; and
forming the first signal metal layers including the first signal via formed in the via hole for the first signal via, and the first heat dissipation metal layers.

7. The method as set forth in claim 1, wherein the forming of the build-up layer includes:
forming an isolation layer on the base substrate;
forming a metal layer on the isolation layer;
forming via holes for the second signal vias in the isolation layer and the metal layer, and forming a via hole for heat dissipation via penetrating the base substrate and the build-up layer in the thickness direction of the substrate; and
forming the build-up layer by forming the second signal metal layers including the second signal vias in the via holes for the second signal via hole and forming the second heat dissipation metal layers including the heat dissipation via in the via hole for the heat dissipation via.

8. The method as set forth in claim 7, wherein the via hole for the heat dissipation via is formed through a mechanical drilling processing.

9. The method as set forth in claim 1, further comprising forming a solder resist layer having an opening for exposing a pad formed on the build-up layer, after the forming of the build-up layer.

10. A printed circuit board, comprising:
a base substrate having one surface and the other surface, and including first signal metal layers including a first signal via penetrating the base substrate from one surface to the other surface and first heat dissipation metal layers;
a build-up layer being formed on the base substrate, and including second signal metal layers including second signal vias stacked on the first signal via and second heat dissipation metal layers facing the first heat dissipation metal layer; and
a heat dissipation via penetrating the base substrate and the build-up layer in the thickness direction of the substrate,
wherein the heat dissipation via penetrates the first heat dissipation metal layers in the thickness direction to reach the second heat dissipation metal layers.

11. The printed circuit board as set forth in claim 10, wherein the base substrate is made of a copper-clad laminate.

12. The printed circuit board as set forth in claim 10, wherein the first signal via has a sandglass shape.

13. The printed circuit board as set forth in claim 10, wherein the build-up layer further includes an isolation layer including openings for the second signal vias and the heat dissipation via.

14. The printed circuit board as set forth in claim 10, further comprising a solder resist layer having an opening for exposing a pad formed on the build-up layer.
